(19) United States
(12) Patent Application Publication
(10) Pub. No.: US 2019/0393057 A1
(43) Pub. Date: Dec. 26, 2019

(54) SUBSTRATE PROCESSING APPARATUS

(71) Applicant: KOKUSAI ELECTRIC CORPORATION, Tokyo (JP)

(72) Inventors: Satoshi SHIMAMOTO, Toyama-shi (JP); Hiroshi ASHIHARA, Toyama-shi (JP); Kazuyuki TOYODA, Toyama-shi (JP); Naofumi OHASHI, Toyama-shi (JP)

(73) Assignee: KOKUSAI ELECTRIC CORPORATION, Tokyo (JP)

(21) Appl. No.: 16/560,266

(22) Filed: Sep. 4, 2019

Related U.S. Application Data
(62) Division of application No. 15/687,950, filed on Aug. 28, 2017.

(30) Foreign Application Priority Data
Mar. 22, 2017 (JP) 2017-055907

(51) Int. Cl. H01L 21/67; H01L 21/677; C23C 16/52; C23C 16/50; C23C 16/24; H01L 21/687

(52) U.S. Cl. CPC H01L 21/67207; H01L 21/67748; H01L 21/67754; H01L 27/11551; C23C 16/50; C23C 16/24; H01L 21/68771; C23C 16/52

(57) ABSTRACT

A substrate processing apparatus includes: a single frequency process chamber installed inside a process module and for processing a substrate on which an insulating film is formed; a two-frequency process chamber installed adjacent to the single frequency process chamber inside the process module and for processing the substrate processed in the single frequency process chamber; a gas supply part configured to supply a silicon-containing gas containing at least silicon and an impurity to each of the process chambers; a plasma generation part connected to each of the process chambers; an ion control part connected to the two-frequency process chamber; a substrate transfer part installed inside the process module and configured to transfer the substrate between the single frequency process chamber and the two-frequency process chamber; and a controller configured to control at least the gas supply part, the plasma generation part, the ion control part, and the substrate transfer part.

### CROSS-REFERENCE TO RELATED APPLICATION

This application is a divisional of U.S. patent application Ser. No. 15/687,950 filed Aug. 28, 2017, based upon and claims the benefit of priority from Japanese Patent Application No. 2017-055907, filed on Mar. 22, 2017, the entire contents of which are incorporated herein by reference.

### TECHNICAL FIELD

The present disclosure relates to a substrate processing apparatus.

### BACKGROUND

Recently, semiconductor devices tend to be highly integrated. As one method of realizing this, a three-dimensional structure in which electrodes or the like are three-dimensionally arranged has been proposed.

In a process of forming a three-dimensional structure of a flash memory, it is necessary to alternately laminate an insulating film and a sacrificial film. However, due to a difference in thermal expansion coefficient between the insulating film and the sacrificial film, stress is applied to a silicon wafer, causing a phenomenon in which the laminated film is broken down in the formation process of the three-dimensional structure. Such a phenomenon may lead to a degradation in characteristics of the semiconductor device.

### SUMMARY

Some embodiments of the present disclosure provide a technique capable of forming a semiconductor device with excellent characteristics even in a flash memory having a three-dimensional structure.

According to one embodiment of the present disclosure, there is provided a substrate processing apparatus, including: a single frequency process chamber installed inside a process module and configured to process a substrate on which an insulating film is formed; a two-frequency process chamber installed adjacent to the single frequency process chamber inside the process module and configured to process the substrate processed in the single frequency process chamber; a gas supply part configured to supply a silicon-containing gas containing at least silicon and an impurity to each of the single frequency process chamber and the two-frequency process chamber; a plasma generation part connected to each of the single frequency process chamber and the two-frequency process chamber; an ion control part connected to the two-frequency process chamber; a substrate transfer part installed inside the process module and configured to transfer the substrate between the single frequency process chamber and the two-frequency process chamber; and a controller configured to control at least the gas supply part, the plasma generation part, the ion control part, and the substrate transfer part.

### BRIEF DESCRIPTION OF THE DRAWINGS

FIG. 1 is an explanatory view illustrating a manufacturing flow of a semiconductor device according to an embodiment of the present disclosure.

FIG. 2 is an explanatory view illustrating a process state of a wafer according to an embodiment.

FIG. 3 is an explanatory view illustrating a process state of a wafer according to an embodiment.

FIG. 4 is an explanatory view illustrating a process state of a wafer according to an embodiment.

FIGS. 5A and 5B are explanatory views illustrating a process state of a wafer according to an embodiment.

FIG. 6 is an explanatory view illustrating a process state of a wafer according to an embodiment.

FIG. 7 is an explanatory view illustrating a process state of a wafer according to an embodiment.

FIG. 8 is an explanatory view illustrating a process state of a wafer according to an embodiment.

FIG. 9 is an explanatory view illustrating a substrate processing apparatus according to an embodiment.

FIG. 10 is an explanatory view illustrating a substrate processing apparatus according to an embodiment.

FIG. 11 is an explanatory view illustrating a substrate processing apparatus according to an embodiment.

FIG. 12 is an explanatory view illustrating a substrate processing apparatus according to an embodiment.

FIG. 13 is an explanatory view illustrating a substrate processing apparatus according to an embodiment.

FIG. 14 is an explanatory view illustrating a substrate processing apparatus according to an embodiment.

FIGS. 15A and 15B are explanatory views illustrating a process state of a wafer according to an embodiment.

FIGS. 16A and 16B are explanatory views illustrating a process state of a wafer according to a Comparative example.

FIG. 17 is an explanatory view illustrating a process state of a wafer according to a Comparative example.

FIG. 18 is an explanatory view illustrating a substrate processing apparatus according to an embodiment.

FIGS. 19A and 19B are explanatory views illustrating a process state of a wafer according to an embodiment.

### DETAILED DESCRIPTION

### First Embodiment

Embodiments of the present disclosure will now be described.

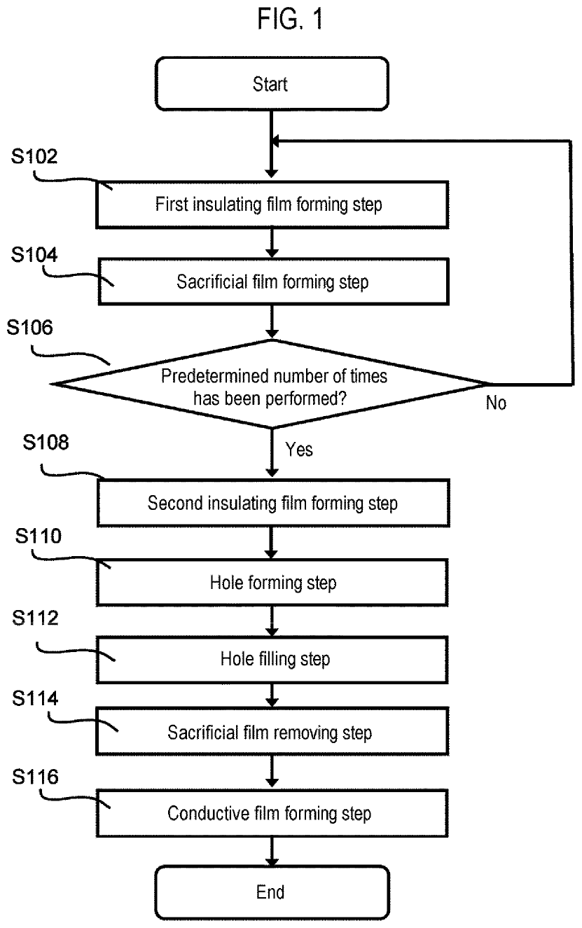

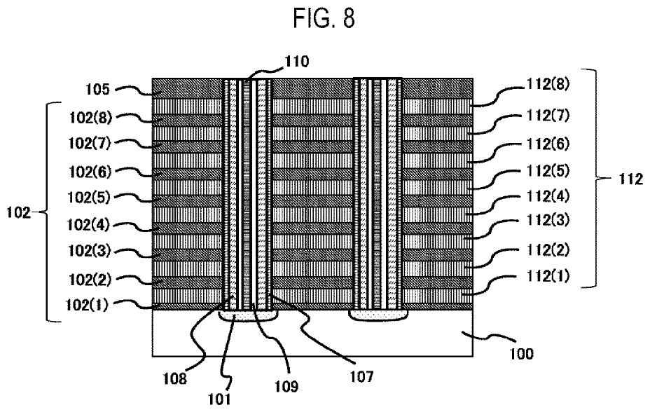

One of the processes of manufacturing a semiconductor device will be described with reference to FIG. 1. In this process, a semiconductor device having a three-dimensional structure in which electrodes are three-dimensionally arranged is formed. As illustrated in FIG. 8, this semiconductor device has a laminate structure in which an insulating film 102 and an electrode 112 are alternately laminated on a wafer 100 as a substrate. A specific flow will be described hereinbelow.

### (S102)

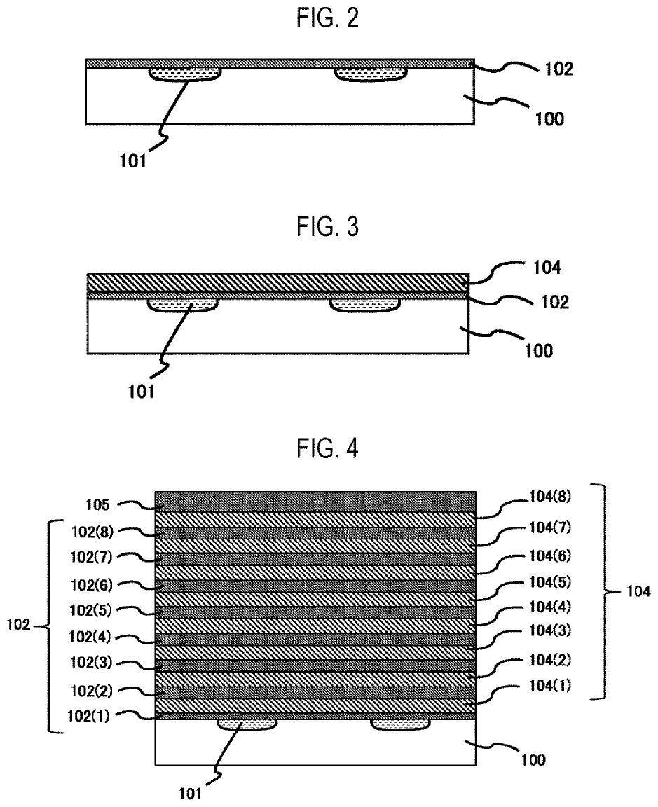

A first insulating film forming step S102 will be described with reference to FIG. 2. FIG. 2 is a view illustrating an insulating film 102 formed on a wafer 100. A common source line (CSL) 101 is formed in the wafer 100. The insulating film 102 will also be referred to as a first insulating film.

In this step, the insulating film 102 is formed on the wafer 100. The insulating film 102 is formed by a silicon oxide (SiO) film. The insulating film 102 is formed by heating the wafer 100 to a predetermined temperature and supplying a silicon-containing gas having a silicon component as a main ingredient and an oxygen-containing gas having an oxygen component as a main ingredient onto the wafer 100. This processing is performed by an oxide film forming apparatus configured as a general apparatus.

### (S104)

A sacrificial film forming step S104 will be described with reference to FIG. 3. At this step, a sacrificial film 104 is formed on the insulating film 102. The sacrificial film 104 is removed in a sacrificial film removing step S114 which will be described later, and has an etching selectivity to the insulating film 102. The etching selectivity refers to a property in which the sacrificial film is likely to be etched and the insulating film is unlikely to be etched when being exposed to an etchant.

The sacrificial film 104 is formed by, for example, a silicon nitride (SiN) film. The sacrificial film 104 is formed by heating the wafer 100 to a predetermined temperature and supplying a silicon-containing gas having a silicon component as a main ingredient and a nitrogen-containing gas having a nitrogen component as a main ingredient onto the wafer 100. As will be described hereinbelow, the silicon-containing gas contains an impurity such as, e.g., chlorine or the like. Details thereof will be described later. However, due to a difference in formation mechanism, a heating temperature of the wafer 100 in the sacrificial film forming step S104 is different from that in the insulating film forming step S102. The silicon-containing gas and the nitrogen-containing gas used in this step will be collectively referred to as a sacrificial film forming gas, or simply to a process gas.

When forming the sacrificial film 104, a film stress of the sacrificial film 104 is processed such that it approximates a film stress of the insulating film 102.

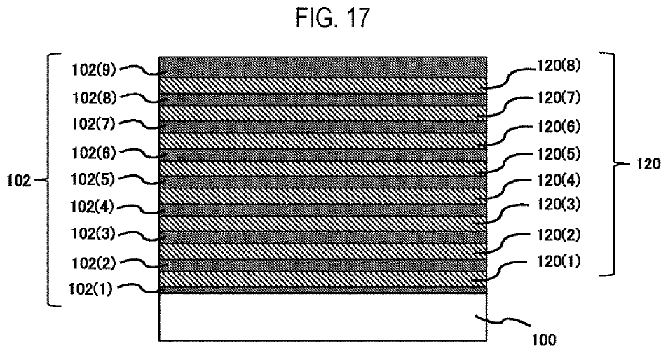

Hereinafter, the reason for approximating the film stress will be described with reference to FIG. 17 which is the Comparative example. In FIG. 17, as an example, a case where the sacrificial film is a sacrificial film 120 and the film stress thereof does not approximate that of an insulating film 102 is illustrated. That is to say, the insulating film 102 and the sacrificial film 120 are alternately laminated without performing the approximation process. The insulating film 102 is made up of an insulating film 102(1), an insulating film 102(2), . . . , and an insulating film 102(8) sequentially from below. Furthermore, the sacrificial film 120 is made up of a sacrificial film 120(1), a sacrificial film 120(2), . . . , and a sacrificial film 120(8) sequentially from below. As described above, the insulating film 102 is formed by heating the wafer 100 to a predetermined temperature and supplying a silicon-containing gas and an oxygen-containing gas onto the wafer 100. The sacrificial film 120 is also formed by heating the wafer 100 to a predetermined temperature different from that of the insulating film 102 and supplying a silicon-containing gas and a nitrogen-containing gas onto the wafer 100.

However, it is generally known that the SiO film has high compressive stress and the SiN film has high tensile stress. That is to say, the SiO film and the SiN film have opposite characteristics with respect to the film stress. The property of these stresses becomes prominent when the films are heated.

In FIG. 17, the formation of the insulating film 102 configured by the SiO film and the formation of the sacrificial film 120 configured by the SiN film are repeated. In some films, the wafer 100 is heated in a state in which both the insulating film 102 and the sacrificial film 120 exist. Thus, the difference in stress between the insulating film 102 and the sacrificial film 120 is high thereby causing, for example, a film delamination between the insulating film 102 and the sacrificial film 120. This may lead to the breakdown of the semiconductor device, a yield reduction, or a property deterioration.

For example, when forming the sacrificial film 120(5), the wafer 100 is heated to form the SiN film. At this time, the insulating film 102(1) to the insulating film 102(5) formed under the sacrificial film 120(5) increase in compressive stress, and the sacrificial film 120(1) to the sacrificial film 120(4) increase in tensile stress. Thus, a difference in stress occurs between the insulating film 102 and the sacrificial film 120. The difference in stress may lead to the breakdown of the semiconductor device, or the like.

In order to reduce such a difference in stress, in the sacrificial film forming step S104, the film stress of the sacrificial film 104 is processed such that it approximates the film stress of the insulating film 102. Details of this process method will be described later.

### (S106)

In this step, it is determined whether a set of the first insulating film forming step S102 and the sacrificial film forming step S104 mentioned above has been performed a predetermined number of times. That is to say, it is determined whether the combination of the insulating film 102 and the sacrificial film 104 in FIG. 4 has been laminated by a predetermined number. In the present embodiment, for example, eight insulating films (the insulating film 102(1) to the insulating film 102(8)) and eight sacrificial films 104 (a sacrificial film 104(1) to a sacrificial film 104(8)) are alternately formed as eight layers. Furthermore, the sacrificial film 104 is made up of sacrificial film 104(1), sacrificial film 104(2), . . . , sacrificial film 104(8) sequentially from below.

If it is determined in step S106 that the combination has not been performed the predetermined number of times, “NO” is selected and the process returns to the first insulating film forming step S102. If it is determined that the combination has been performed the predetermined number of times, namely if it is determined that the predetermined number of layers has been formed, “YES” is selected and the process goes to a second insulating film forming step S108. Furthermore, while an example in which the insulating films 102 and sacrificial films 104 has been described to be formed as eight layers, respectively, the present disclosure is not limited thereto. In some embodiments, the insulating films 102 and sacrificial films 104 may be formed as nine or more layers, respectively.

### (S108)

Next, the second insulating film forming step S108 will be described. In this step, an insulating film 105 illustrated in FIG. 4 is formed. The insulating film 105 is formed by the same method as that of the insulating film 102 and is formed on the uppermost sacrificial film 104.

### (S110)

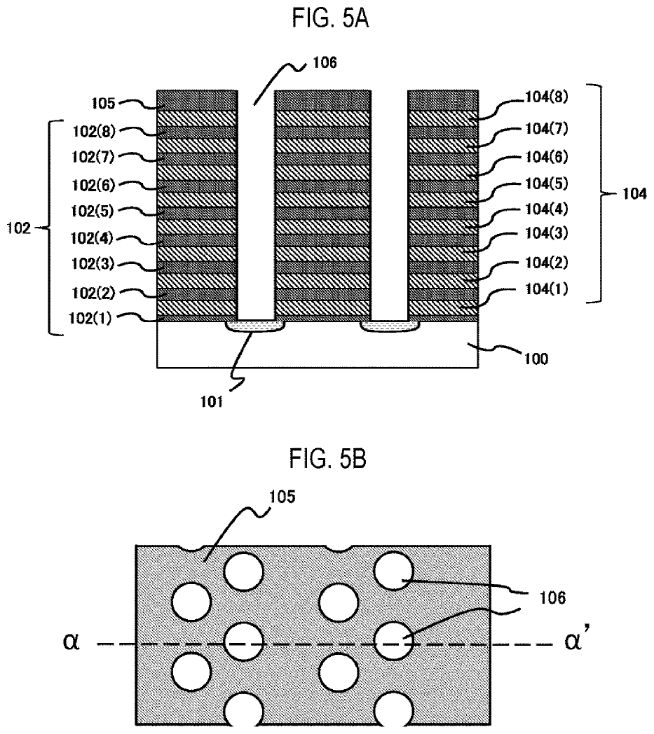

Next, a hole forming step S110 will be described with reference to FIGS. 5A and 5B. FIG. 5A is a side view like FIG. 4, and FIG. 5B is a top view of the configuration of FIG. 5A. Furthermore, a cross sectional view taken along line a-a′ of FIG. 5B corresponds to FIG. 5A.

In this step, holes 106 are formed in the laminate structure of the insulating films 102 and 105 and the sacrificial film 104. As illustrated in FIG. 5A, each of the holes 106 is formed to expose the CSL 101. As illustrated in FIG. 5B, a plurality of holes 106 are formed in the plane of the insulating film 105.

### (S112)

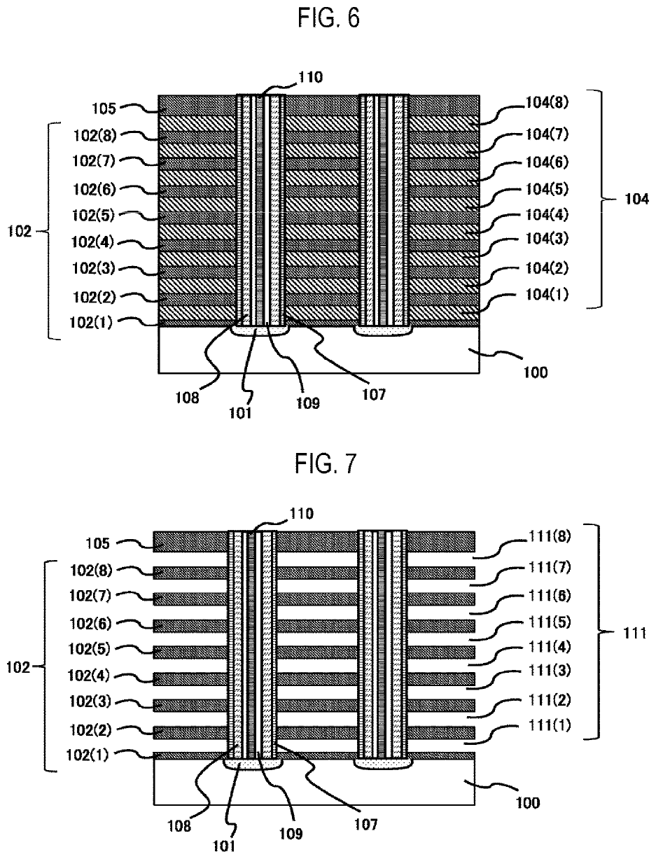

Next, a hole filling step S112 will be described with reference to FIG. 6. In this step, the inner side of the hole 106 formed in step S110 is filled with a laminated film 108 or the like. A protective film 107, the laminated film 108 of insulating film between gate electrodes-charge trap film-tunnel insulating film, a channel polysilicon film 109, and a filling insulating film 110 are formed within the hole 106 sequentially from an outer peripheral side. Each film is formed in a cylindrical shape.

For example, the protective film 107 is configured by an SiO or metal oxide film. The laminated film 108 of the insulating film between gate electrodes-charge trap film-tunnel insulating film is made up of an SiO—SiN—SiO film. In order to avoid damage to the laminated film 108 when removing the sacrificial film 104, the protective film 107 is formed on a surface of an inner wall of the hole 106 to protect the laminated film 108.

### (S114)

Next, the sacrificial film removing step S114 will be described with reference to FIG. 7. In the sacrificial film removing step S114, the sacrificial film 104 is removed by wet etching. As a result of removing the sacrificial film 104, voids 111 are formed at positions where the sacrificial film 104 was formed. Herein, a void 111(1), a void 111(2), . . . , a void 111(8) are formed sequentially from below.

### (S116)

Next, a conductive film forming step S116 will be described with reference to FIG. 8. In the conductive film forming step S116, a conductive film 112 serving as an electrode is formed in the void 111. The conductive film is made of, for example, tungsten or the like. Here, the conductive film 112 is made up of a conductive film 112(1), a conductive film 112(2), . . . , a conductive film 112(8) sequentially from below.

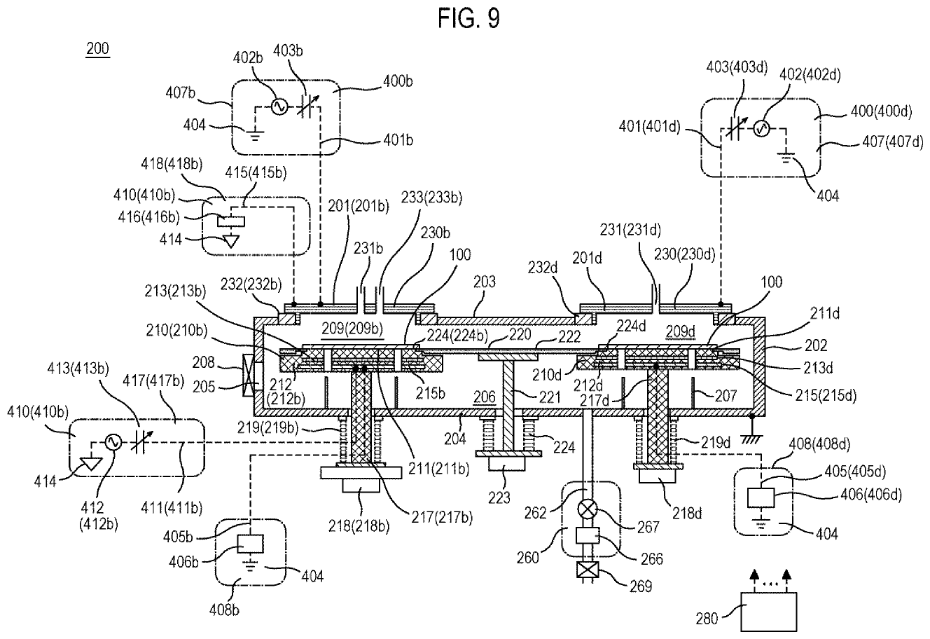

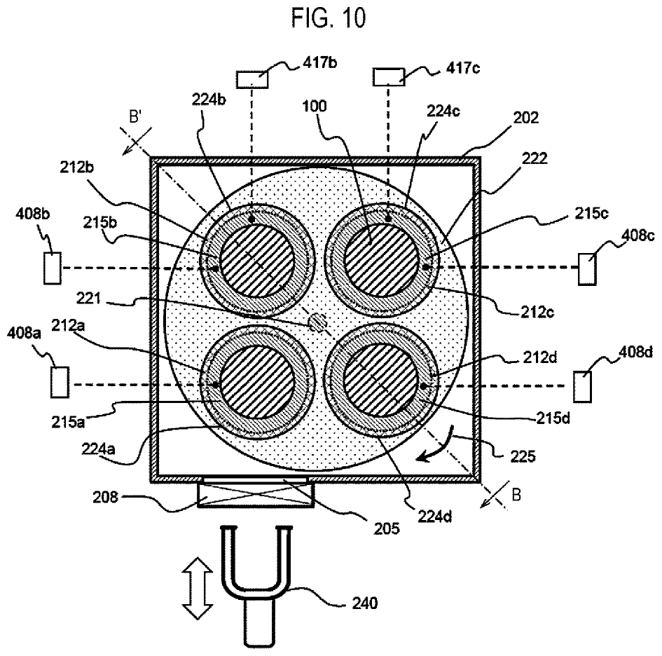

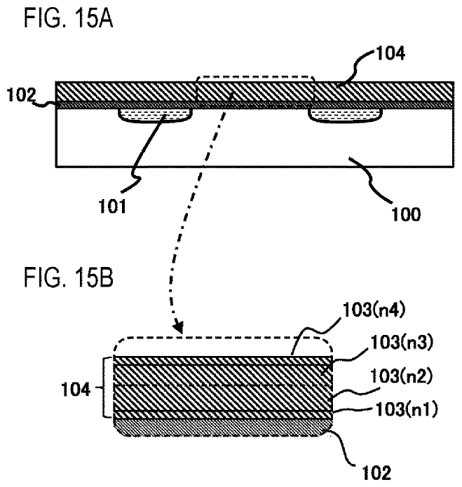

Subsequently, a substrate processing apparatus 200 used in the sacrificial film forming step S104 and a forming method will be described. The substrate processing apparatus 200 will be described with reference to FIGS. 9 to 14. The method of forming the sacrificial film will be described with reference to FIGS. 15A and 15B.

### (Substrate Processing Apparatus)

### (Process Vessel)

As illustrated in the drawing, the substrate processing apparatus 200 includes a vessel 202. The vessel 202 will also be referred to as a process module. The vessel 202 is configured as, for example, a flat airtight vessel having a rectangular cross section. Furthermore, the vessel 202 is made of a metal material such as, e.g., aluminum (Al) or stainless steel (SUS). A process chamber 201 in which a wafer 100 such as a silicon wafer or the like is processed and a transfer chamber 206 through which the wafer 100 passes when the wafer 100 is transferred to the process chamber 201 are formed inside the vessel 202. The process chamber 201 includes a shower head 230, a substrate mounting part 210 and the like which will be described later. In addition, the transfer chamber 206 is defined by a rotary tray 222 and a lower portion 204 of the process vessel 202.

A substrate loading/unloading port 205 is formed in a side surface of the vessel 202 adjacent to the gate valve 208. The wafer 100 is transferred to and from a transfer chamber (not shown) through the substrate loading/unloading port 205. A plurality of lift pins 207 are installed in the lower portion 204.

The substrate mounting part 210 configured to support the wafer 100 is disposed in the process chamber 201. The substrate mounting parts 210 are arranged at a plurality of locations. The arrangement of the plurality of substrate mounting parts 210 will be described with reference to FIG. 10. FIG. 10 illustrates the substrate processing apparatus 200, particularly the vicinity of the rotary tray 222 when viewed from above. An arm 240 is disposed outside the process vessel 202 and has a function of transferring the wafer 100 to and from the process vessel 202. A vertical cross sectional view taken along line B-B′ corresponds to FIG. 9.

There are at least four substrate mounting tables 212, which are one component of the substrate mounting part 210. Specifically, a substrate mounting table 212a, a substrate mounting table 212b, a substrate mounting table 212c, and a substrate mounting table 212d are arranged in a clockwise direction from a position facing the substrate loading/unloading port 205. Thus, the wafer 100 carried into the vessel 202 is transferred in the order of the substrate mounting table 212a, the substrate mounting table 212b, the substrate mounting table 212c, and the substrate mounting table 212d.

The substrate mounting part 210 mainly includes substrate mounting surfaces 211 (a substrate mounting surface 211a to a substrate mounting surface 211d) on each of which the wafer 100 is mounted, substrate mounting tables 212 (the substrate mounting table 212a to the substrate mounting table 212d) respectively having the substrate mounting surface 211, bias electrodes 215 (a bias electrode 215a to a bias electrode 215d), and shafts 217 (a shaft 217a to a shaft 217b) that respectively support the substrate mounting tables 212. Furthermore, the substrate mounting part 210 includes heaters 213 (213a to 213d) as a heating source. Through holes through which the lift pins 207 pass are formed at positions corresponding to the lift pins 207 in the substrate mounting table 212, respectively.

The substrate placing tables 212 (the substrate placing tables 212a to 212d) are respectively supported by the shafts 217 (the shafts 217a to 217d). The shafts 217 penetrate the lower portion 204 of the process vessel 202, and are connected to respective elevating parts 218 (elevating parts 218a to 218d) outside the process vessel 202. The shafts 217 are insulated from the process vessel 202.

The elevating parts 218 are configured to elevate or lower the shafts 217 and the substrate mounting tables 212. The periphery of the lower end portion of each of the shafts 217 is covered with a bellows 219 (bellows 219a to 219d), so that the interior of the vessel 202 is hermetically sealed.

When the wafer 100 is transferred, the substrate mounting table 212 is lowered such that the substrate mounting surface 211 and the rotary tray 222 are located at a position facing the substrate loading/unloading port 205. As illustrated in FIG. 9, when the wafer 100 is processed, the substrate mounting table 212 is elevated up to a position at which the wafer 100 is processed within a process space 209.

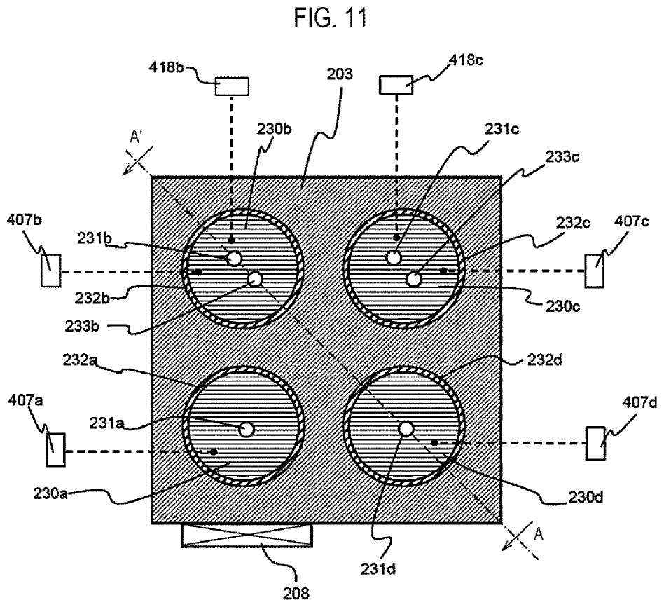

Shower heads 230 (230a to 230d), which are gas dispersion mechanisms, are installed at a position at which a lid portion 203 of the process vessel 202 is installed and which faces each of the substrate mounting surfaces 211. As illustrated in FIG. 11, the plurality of shower heads 230 are arranged uniformly when viewed from above. The shower heads 230 are supported by the lid portion 203 via insulating rings 232 (232a to 232d). The shower heads 230 and the process vessel 202 are insulated from each other by the insulating rings 232. Gas introduction holes 231 (231a to 231d) are formed in each of the shower heads 230 (230a to 230d) in the lid portion 203. Each of the gas introduction holes 231 communicates with a common gas supply pipe 301 described hereinbelow. A vertical cross sectional view taken along line A-A′ in FIG. 11 corresponds to FIG. 9.

A gas introduction hole 233 is formed in each of the shower head 230b and the shower head 203c to connect each of the shower head 230b and the shower head 203c with an assist gas supply part described hereinbelow. Specifically, as illustrated in FIG. 11, a gas introduction hole 233b is formed in the shower head 230b, and a gas introduction hole 233c is formed in the shower head 230c. With such a structure, it becomes possible to supply an assist gas to a two-frequency process chamber which will be described later.

A space between each shower head 230 and each substrate mounting surface 211 will be referred to as the process space 209. In the present embodiment, a space between the shower head 230a and the substrate mounting surface 211a will be referred to as a process space 209a. A space between the shower head 230b and the substrate mounting surface 211b will be referred to as a process space 209b. A space between the shower head 230c and the substrate mounting surface 211c will be referred to as a process space 209c. A space between the shower head 230d and the substrate mounting surface 211d will be referred to as a process space 209d.

Furthermore, a structure constituting the process space 209 will be referred to as the process chamber 201. In the present embodiment, a structure which constitutes the process space 209a and includes at least the shower head 230a and the substrate mounting surface 211a will be referred to as a process chamber 201a. A structure which constitutes the process space 209b and includes at least the shower head 230b and the substrate mounting surface 211b will be referred to as a process chamber 201b. A structure which constitutes the process space 209c and includes at least the shower head 230c and the substrate mounting surface 211c will be referred to as a process chamber 201c. A structure which constitutes the process space 209d and includes at least the shower head 230d and the substrate mounting surface 211d will be referred to as a process chamber 201d.

In addition, while in the above embodiment, the process chamber 201 has been described to include at least the shower head 230a and the substrate mounting surface 211a, any structure may be used as long as it constitutes the process space 209 in which the wafer 100 is processed. It is to be understood that, depending on a structure of the apparatus, the structure of the shower head 230 may be modified in any shape.

As illustrated in FIG. 10, each of the substrate mounting parts 210 is disposed circumferentially around a shaft 221 of a substrate rotation part 220. The rotary tray 222 is installed on the shaft 221. Furthermore, the shaft 221 is configured to penetrate the lower portion 204 of the process vessel 202. A rotation elevating part 223 is installed outside the process vessel 202, namely at a side different from a position of the rotary tray 222. The rotation elevating part 223 is configured to elevate or lower the shaft 221 or rotates it. With the rotation elevating part 223, it is possible to elevate or lower the shaft 221 independently from each of the substrate mounting parts 210. A bellows 224 is installed around a lower end of the shaft 221 and outside the process vessel 202. The rotational direction is defined as, for example, a direction of the arrow 225 (clockwise direction) in FIG. 10. The shaft 221, the rotary tray 222, and the rotation elevating part 223 will be collectively referred to as a substrate rotation part. The substrate rotation part 220 will also be referred to as a substrate transfer part.

The rotary tray 222 is formed in, for example, a circular shape. Hole portions 224 (224a to 224d) having at least the approximately same diameter as that of the substrate mounting surface 211 are formed to have the same number as that of the substrate mounting parts 210 at an outer peripheral end of the rotary tray 222. Furthermore, the rotary tray 222 has a plurality of hooks protruding toward the inside of the hole portions 224. The hooks are configured to support the rear surface of the wafer 100. In the present embodiment, “loading the wafer 100 in the hole portions 224” means that the wafer 100 is mounted on the hooks.

As the shaft 221 elevates, the rotary tray 222 is located at a position higher than the substrate mounting surface 211. At this time, the wafer 100 mounted on the substrate mounting surface 211 is picked up by the hooks. Furthermore, as the shaft 221 rotates, the rotary tray 222 is rotated so that the picked-up wafer 100 is moved onto the subsequent substrate mounting surface 211. For example, the wafer 100 mounted on the substrate mounting surface 211b is moved onto the substrate mounting surface 211c. Thereafter, the shaft 221 is lowered so that the rotary tray 222 is lowered. At this time, the hole portions 224 are lowered until they are positioned below the substrate mounting surface 211, and the wafer 100 is mounted on the substrate mounting surface 211.

### (Exhaust System)

An exhaust system 260 configured to exhaust the atmosphere of the vessel 202 will be described. An exhaust pipe 262 is connected to the vessel 202 so as to communicate with the process chamber 201. An auto pressure controller (APC) 266 which is a pressure controller for controlling the interior of the process chamber 201 to reach a predetermined pressure is installed in the exhaust pipe 262. The APC 266 includes a valve element (not shown) whose opening degree is adjustable, and is configured to adjust the conductance of the exhaust pipe 262 according to an instruction provided from a controller 280. In addition, a valve 267 is installed in the exhaust pipe 262 at the upstream side of the APC 266. The exhaust pipe 262, the valve 267, and the APC 266 will be collectively referred to as the exhaust system 260.

Furthermore, a dry pump (DP) 269 is installed. The DP 269 is configured to exhaust the atmosphere of the process chamber 201 via the exhaust pipe 262.

### (Gas Supply Part)

### (Process Gas Supply Part)

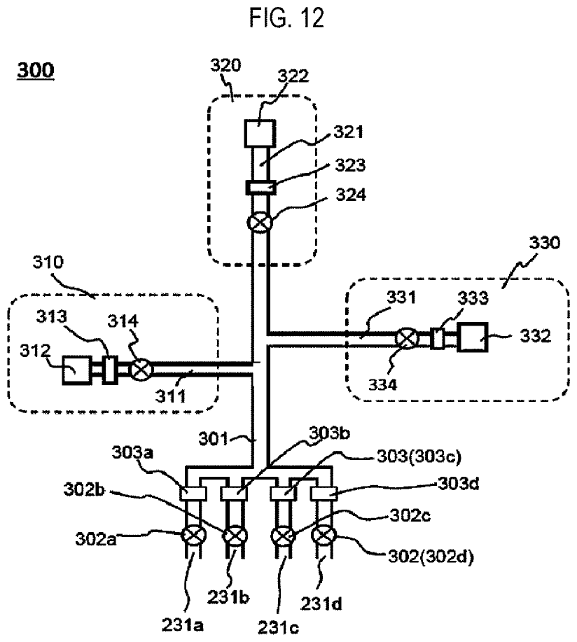

Next, a process gas supply part 300 will be described with reference to FIG. 12. Here, the process gas supply part 300 connected to each gas introduction hole 231 will be described. Furthermore, only the process gas supply part 300, or both the process gas supply part 300 and an assist gas supply part 340 (to be described later) will be collectively referred to as a gas supply part.

The shower head 320 is connected to the common gas supply pipe 301 via the valves 302 (302a to 302d) and mass flow controllers 303 (303a to 303d) so that the gas introduction holes 231 and the common gas supply pipe communicate with each other. The supply amount of gas to each process chamber is adjusted using the valves 302 (302a to 302d) and the mass flow controllers 303 (303a to 303d). A first gas supply pipe 311, a second gas supply pipe 321, and a third gas supply pipe 331 are connected to the common gas supply pipe 301.

### (First Gas Supply System)

A first gas source 312, a mass flow controller (MFC) 313, which is a flow rate controller (flow rate control part), and a valve 314, which is an opening/closing valve, are installed in the first gas supply pipe 311 sequentially from the respective upstream side.

The first gas source 312 is a source of a first gas containing a first element (also referred to as a “first element-containing gas”). The first element-containing gas is a precursor gas, i.e., one of the process gases. Here, the first element is silicon (Si). That is to say, the first element-containing gas is a silicon-containing gas. Specifically, as the silicon-containing gas, it may be possible to use a dichlorosilane (SiH₂Cl₂, also referred to as DCS) gas or a hexachlorodisilane (Si₂Cl₆, also referred to as HCDS) gas.

A first gas supply system 310 (also referred to as a silicon-containing gas supply system) is mainly made up of the first gas supply pipe 311, the MFC 313, and the valve 314.

### (Second Gas Supply System)

A second gas source 322, an MFC 323, which is a flow rate controller (flow rate control part), and a valve 324, which is an opening/closing valve, are installed in the second gas supply pipe 321 sequentially from the respective upstream side.

The second gas source 322 is a source of a second gas containing a second element (hereinafter also referred to as a “second element-containing gas”). The second element-containing gas is one of the process gases. Furthermore, the second element-containing gas may be regarded as a reaction gas.

Here, the second element-containing gas contains a second element different from the first element. The second element is, for example, nitrogen (N). In the present embodiment, the second element-containing gas is, for example, a nitrogen-containing gas. Specifically, as the nitrogen-containing gas, it may be possible to use an ammonia (NH₃) gas.

A second gas supply system 320 (also referred to as a reaction gas supply system) is mainly made up of the second gas supply pipe 321, the MFC 323, and the valve 324.

### (Third Gas Supply System)

A third gas source 332, an MFC 333, which is a flow rate controller (flow rate control part), and a valve 334, which is an opening/closing valve, are installed in the third gas supply pipe 331 sequentially from the respective upstream side.

The third gas source 332 is a source of an inert gas. The inert gas is, for example, a nitrogen (N₂) gas.

A third gas supply system 330 is mainly made up of the third gas supply pipe 331, the MFC 333, and the valve 334.

The inert gas supplied from the third gas source 332 acts as a purge gas for purging the gas remaining within the vessel 202 or the shower head 230 in the substrate processing process.

Furthermore, any one of the first gas supply system, the second gas supply system, and the third gas supply system, or a combination thereof will be referred to as the process gas supply part 300.

### (Assist Gas Supply Part)

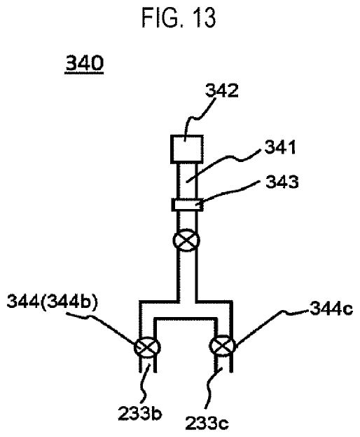

Next, an assist process gas supply part 340 communicating with the gas introduction holes 233b and 233c will be described with reference to FIG. 13.

A fourth gas supply pipe 341 is connected to the shower head 320 so as to communicate with the gas introduction hole 233b and the gas introduction hole 233c.

An assist gas source 342, an MFC 343, and valves 344 (344b and 344c) are installed in the fourth gas supply pipe 341 from the respective upstream side. As the assist gas, it may be possible to use, for example, a gas having a large molecular size such as argon (Ar). The gas supply pipe 341, the MFC 343, and the valve 344 will be collectively referred to as the assist gas supply part 340. Furthermore, the assist gas source 342 may be included in the assist gas supply part 340.

### (Plasma Generation Part)

Next, returning to FIGS. 9, 10, and 11, a plasma generation part 400 will be described.

The plasma generation part 400 is to generate plasma in each of the process spaces 209 (209a to 209d). In the present embodiment, the plasma generation part 400 includes a first plasma generation part 400a for generating plasma in the process space 209a, a second plasma generation part 400b for generating plasma in the process space 209b, a third plasma generation part 400c for generating plasma in the process space 209c, and a fourth plasma generation part 400d for generating plasma in the process space 209d.

Subsequently, a specific configuration of the plasma generation part 400 will be described. Furthermore, the first plasma generation part 400a, the second plasma generation part 400b, the third plasma generation part 400c, and the fourth plasma generation part 400d have the same configuration, and thus, a specific configuration thereof will be described as the plasma generation part 400.

High-frequency power supply lines 401 (401a to 401d), which are one component of the plasma generation part 400, are connected to the shower heads 230 (230a to 230d), respectively. High-frequency power sources 402 (402a to 402d) and matchers 403 (403a to 403d) are installed in the high-frequency power supply lines 401 sequentially from the respective upstream sides. The high-frequency power sources 402 are connected to a ground 404.

High-frequency power output lines 405 (405a to 405d) are connected to the bias electrodes 215 (215a to 215d) of the substrate mounting part 210 disposed to face the shower heads 230. High pass filters (hereinafter, referred to HPFs) 406 (406a to 406d) are installed in the high-frequency power output lines 405. The HPFs 406 are connected to a ground 404.

The high-frequency power supply lines 401 (401a to 401d), the high-frequency power sources 402 (402a to 402d), and the high-frequency power output lines 405 (405a to 405d) will be mainly collectively referred to as the plasma generation parts 400 (400a to 400d). Furthermore, the high-frequency power supply lines 401 (401a to 401d) and the high frequency power sources 402 (402a to 402d) which are the high-frequency power supply side will be collectively referred to as high-frequency power supply parts 407 (407a to 407d). The high-frequency power output lines 405 (405a to 405d) which are the high-frequency power output side will be referred to as high-frequency power output parts 408 (408a to 408d). In addition, the HPFs 406 (406a to 406d) may be included in the high-frequency power output parts 408 (408a to 408d).

### (Ion Control Part)

Next, an ion control part 410 will be described. The ion control part 410 is configured to supply a low-frequency power to the process space 209 in which a second layer 103(n2) and a third layer 103(n3) (both to be described later) are formed. For example, in the present embodiment, the ion control part 410 is connected to the process chamber 201b in which the second layer 103(n2) is formed and the process chamber 201c in which the third layer 103(n3) is formed.

Furthermore, the process chamber 201 (the process chambers 201a and 201d in the present embodiment) to which the plasma generation part 400 is connected and the ion control part 410 is not connected will also be referred to as a single frequency process chamber. The process chamber (the process chambers 201b and 201c in the present embodiment) to which both the plasma generator 400 and the ion control part 410 are connected will also referred to as the two-frequency process chamber.

A specific example will be described below. The low-frequency power supply lines 411 (411b and 411c) constituting a portion of the ion control part 410 are electrically connected to the bias electrodes 215 (215b and 215c) in the two-frequency process chambers (the process chamber 201b and process chamber 201c). In the present embodiment, the low-frequency power supply line 411b of the ion control part 410b is connected to the bias electrode 215b, and the low-frequency power supply line 411c of the ion control part 410c is connected to the bias electrode 215c.

Low-frequency power sources 412 (412b and 412c) and matchers 413 (413b and 413c) are installed in the low-frequency power supply lines 411 (411b and 411c) sequentially from the respective upstream sides. The low-frequency power sources 412 (412b and 412c) are connected to a ground 414. The low-frequency power source 412b and the matcher 413b are installed in the low-frequency power supply line 411b sequentially from the respective upstream side. The low-frequency power source 412b is connected to the ground 414. Furthermore, the low-frequency power source 412c and the matcher 413c are installed in the low-frequency power supply line 411c sequentially from the respective upstream side. The low-frequency power source 412c is connected to the ground 414.

Low-frequency power output lines 415 (415b and 415c) are connected to the shower heads 230b and 230c, respectively. Low pass filters (hereinafter, referred to as LPFs) 416 (416b and 416c) which are a portion of the ion control part 410 are installed in the low-frequency power output lines 415. The LPFs 416 are connected to the ground 414.

The low-frequency power supply lines 411 (411b and 411c), the low-frequency power sources 412 (412b and 412c), and the low-frequency power output lines 415 (415b and 415c) will be mainly collectively referred to as the ion control parts 410 (410b and 410c). Furthermore, the low-frequency power supply lines 411 (411b and 411c) and the low-frequency power sources 412 (412b and 412c), which are the low-frequency power supply side, will be collectively referred to as the low frequency power source parts 417 (417b and 417c). The low-frequency power output lines 415 (415b and 415c) which are the low-frequency power output side will be referred to as low-frequency power output parts 418 (418b and 418c). In addition, the LPFs 416 (416b and 416c) may be included in the low-frequency power output part 418.

For example, a low frequency refers to a range of about 1 to 400 KHz and a high frequency refers to about 13.56 MHz.

### (Controller)

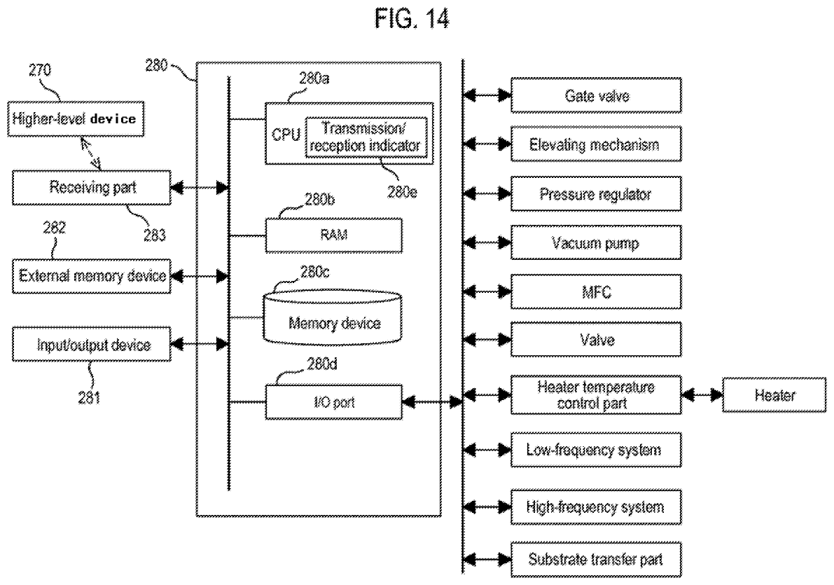

The substrate processing apparatus 200 includes the controller 280 configured to control the operations of the respective parts of the substrate processing apparatus 200. As illustrated in FIG. 14, the controller 280 includes at least an operation part (CPU) 280 a, a temporary memory part 280b, a memory part 280c, and an I/O port 280d. The controller 280 is connected to each part of the substrate processing apparatus 200 via the I/O port 280d, and invokes a program or a recipe from the memory part 280c according to an instruction from a higher-level device 270 or the user, and controls, according to the contents thereof, the operation of each part such as the ion control part 410 or the plasma generation part 400. The transmission/reception control is performed by, for example, a transmission/reception indicator 280e in the operation part 280a. Furthermore, the controller 280 may be configured as a dedicated computer or as a general-purpose computer. For example, the controller 280 according to the present embodiment may be configured by installing, on a general-purpose computer, the program stored in an external memory device 282 (for example, a magnetic tape, a magnetic disk such as a flexible disk or a hard disk, an optical disc such as a CD or a DVD, a magneto-optical disc such as an MO, or a semiconductor memory such as a USB memory (USB flash drive) or a memory card) using the external memory device 282. Furthermore, means for supplying the program to the computer is not limited to being supplied via the external memory device 282. For example, the program may be supplied to the computer using a communication means such as the Internet or a dedicated line. Alternatively, the program may be supplied to the computer by receiving information from the higher-level device 270 through a receiving part 283, instead of using the external memory device 282. In addition, an instruction may be issued to the controller 280 using an input/output device 281 such as a keyboard or a touch panel.

Furthermore, the memory part 280c or the external memory device 282 is configured as a non-transitory computer-readable recording medium. Hereinafter, the memory part 280c and the external memory device 282 will be generally and simply referred to as a “recording medium.” When the term “recording medium” is used herein, it may indicate a case of including only the memory part 280c, a case of including only the external memory device 282, or a case of including both the memory part 282c and the external memory device 282.

Subsequently, details of the sacrificial film forming step S104 in FIG. 1 will be described.

### (Sacrificial Film Forming Step S104)

Next, an example in which an HCDS gas is used as a first process gas and an ammonia (NH₃) gas is used as a second process gas to form a sacrificial film 104 will be described. The sacrificial film is formed of a silicon nitride film (SiN film).

In this step, the sacrificial film 104 formed in the present embodiment will be described with reference to FIGS. 15A and 15B. FIGS. 15A and 15B are views illustrating a process state of the wafer 100. FIG. 15A is the same view as that of FIG. 3, and FIG. 15B is an enlarged view of a portion of FIG. 15A. Specifically, FIG. 15B is an enlarged view of portions of the insulating film 102 and the sacrificial film 104. Furthermore, a silicon nitride layer 103(n1), a silicon nitride layer 103(n2), a silicon nitride layer 103(n3), and a silicon nitride layer 103(n4) in FIG. 15B are layers constituting the sacrificial film 104. That is to say, the sacrificial film 104 includes a plurality of silicon nitride layers 103. The silicon nitride layer 103(n1) will also be referred to as a first silicon nitride layer, the nitride layer 103(n2) will also be referred to as a second silicon nitride layer, the nitride layer 103(n3) will also be referred to as a third silicon nitride layer, and the nitride layer 103(n4) will also be referred to as a fourth silicon nitride layer.

However, for example, when the sacrificial film 104 is formed using an HCDS gas and an NH₃ gas in a plasma state, a decomposed HCDS gas and an NH₃ gas in a plasma state exist in the process chamber 201. That is to say, respective components of Si, chlorine (Cl), nitrogen (N), and hydrogen (H) exist in a mixed state in the process chamber 201. In this state, Si and nitrogen are mainly bonded to form the sacrificial film 104 formed of a SiN film.

When forming the sacrificial film 104, both components of chlorine (Cl) and hydrogen (H) as impurities exist in the process chamber 201 in addition to Si and N as main ingredients. Thus, in the process of forming the SiN film, Si may be bonded to Cl or H, or N bonded to Si may be bonded to Cl or H. These components are introduced into the SiN film. As a result of extensive research by the present inventor, it was found that the bond to an impurity is a factor of tensile stress.

As described above, the tensile stress of the sacrificial film 104 leads to a difference in stress from the insulating film 102. Thus, in the present embodiment, when forming the sacrificial film 104, it is configured such that the tensile stress of the sacrificial film 104 approximates the film stress of the insulating film 102. Specifically, as illustrated in FIGS. 15A and 15B, it is configured such that at least a thin silicon nitride layer 103(n1) and a thick silicon nitride layer 103(n2) are formed, and the higher tensile stress of the silicon nitride layer 103(n2) approximates the film stress of the insulating film 102. Furthermore, it is configured such that the tensile stress of the silicon nitride layer 103(n3) approximates to the film stress of the insulating film 102.

### (S201)

First, a substrate loading step S201 of loading the wafer 100 into the vessel 202 will be described.

Furthermore, before the wafer 100 is loaded, the hole portion 224a is in a state of being adjacent to the substrate loading/unloading port 205. Thus, the hole portion 224a is disposed above the substrate mounting surface 211a. In addition, in the present embodiment, an example in which four wafers 100 are processed inside the vessel 202 will be described. In the following description, a wafer 100 firstly introduced into the vessel 202 will be referred to as a first wafer 100, a wafer 100 secondly introduced into the vessel 202 will be referred to as a second wafer 100, a wafer 100 thirdly introduced into the vessel 202 will be referred to as a third wafer 100, and a wafer 100 fourthly introduced into the vessel 202 will be referred to as a fourth wafer 100.

Hereinafter, details will be described.

The arm 240 enters the process chamber 201 from the substrate loading/unloading port 205 and mounts the wafer 100 having the insulating film 102 formed thereon on the hole portion 224 of the rotary tray 220. In the present embodiment, the first wafer 100 is mounted on the hole portion 224a adjacent to the loading/unloading port 205.

After the first wafer 100 is mounted, the rotary tray 220 is lowered. At this time, each substrate mounting surface 211 is relatively elevated to a position higher than a surface of the rotary tray 220. By this operation, the first wafer 100 is mounted on the substrate mounting surface 211a. If the first wafer 100 is mounted on the substrate mounting surface 211a, the gate valve 208 is closed to hermetically seal the interior of the vessel 202.

When the wafer 100 is mounted on each substrate mounting table 212, electric power is supplied to each heater 213 embedded in the substrate mounting table 212 such that the surface of the wafer 100 is controlled to have a predetermined temperature. The temperature of the wafer 100 may be, for example, room temperature to 800 degrees C., specifically room temperature to 700 degrees C. At this time, the temperature of the heater 213 is adjusted by extracting a control value by the controller 280 based on the temperature information detected by a temperature sensor (not shown) and controlling a state of supplying the electric power to the heater 213 by a temperature control part (not shown).

### (S202)

Here, step S202 of forming a silicon nitride layer 103(n1) on the surface of the insulating film 102 will be described. If the wafer 100 is maintained at a predetermined temperature, an HCDS gas is supplied from the first gas supply system 310 to the process chamber 201a and simultaneously, an NH₃ gas is supplied from the second gas supply system 320 to the process chamber 201a.

Subsequently, if the interior of the process chamber 201a reaches a predetermined pressure, the plasma generation part 400 supplies a high frequency into the process chamber 201a. Specifically, the high-frequency power source 402a is operated to supply electric power. A portion of the process gas inside the process chamber 201a is ionized and transitions into a plasma state. The HCDS gas and the NH₃ gas in a plasma state react with each other inside the process chamber 201a and are supplied onto the insulating film 102.

When a predetermined time has lapsed from initiation of the supply of the high frequency, as illustrated in FIGS. 15A and 15B, reaction products are deposited on the insulating film 102 to form a dense silicon nitride layer 103(n1). The silicon nitride layer 103(n1) will also be referred to as a first silicon nitride layer. The thickness of the silicon nitride layer 103(n1) is such that it does not have an affect on the stress of the sacrificial film and is thinner than at least the silicon nitride layer 103(n2).

### (S203)

Here, step S203 of moving the first wafer 100 and loading the second wafer 100 will be described. If the silicon nitride layer 103(n1) is formed on the first wafer 100 after the lapse of a predetermined time, the supply of the process gas is stopped. Thereafter, the rotary tray 224 is elevated to separate the first wafer 100 from the substrate mounting surface 211a. After the separation, the rotary tray 224 is rotated by 90 degrees in a clockwise direction such that the hole portion 224a is moved onto the substrate mounting surface 211b. Upon completion of the rotation, the hole portion 224a is disposed above the substrate mounting surface 211b and the hole portion 224d is disposed above the substrate mounting surface 211a. Upon completion of the rotation, the gate valve 208 is opened and the second wafer 100 is mounted on the hole portion 224d. After each wafer 100 is mounted, each substrate mounting surface 211 is relatively elevated to mount the wafer 100 of the hole portion 224a on the substrate mounting surface 211b and mount the wafer 100 of the hole portion 224d on the substrate mounting surface 211a.

### (S204)

Here, step S204 of processing the wafer 100 in the process chamber 201a and the process chamber 201b will be described.

### (Process in Process Chamber 201a)

The same process as that of step S202 is performed in the process chamber 201a so that a silicon nitride layer 103(n1) is formed on the insulating film 102 of the second wafer 100.

### (Process in Process Chamber 201b)

In the process chamber 201b, a silicon nitride layer 103(n2) is formed on the silicon nitride layer 103(n1) formed on the first wafer 100.

Hereinafter, a specific method will be described.

Once the second wafer 100 is maintained at a predetermined temperature, an HCDS gas is supplied to the process chamber 201b from the first gas supply system 310 and an NH₃ gas is also supplied from the second gas supply system 320.

Subsequently, if the interior of the process chamber 201b reaches a predetermined pressure, the plasma generation part 400 starts to supply a high frequency into the process chamber 201. A portion of the process gas in the process chamber 201b is ionized to be in a plasma state. Furthermore, the controller 280 operates the low-frequency power source 412b of the ion control part 410 to start the supply of a low frequency into the process chamber 201b.

The process gas turns into a high density plasma state by the high frequency and ions of the plasma are irradiated to the wafer 100 on the substrate mounting surface 211b by the low frequency.

Among the gases in a plasma state, Si and nitrogen are mainly bonded and supplied onto the insulating film 102 to form the silicon nitride layer 103(n2). In parallel with this, impurity bonds occur in the process chamber 201b. There is a possibility that the impurity bonds are introduced into the silicon nitride layer 103(n2). Furthermore, the impurity bonds have at least one of, for example, an Si—Cl bond in which Si and Cl are bonded, an Si—H bond in which Si and H are bonded, an Si—NCl bond in which Si—N and Cl are bonded, an Si—NH bond in which Si—N and H are bonded, and the like.

However, in this step, an ion component such as nitrogen or the like is supplied to the impurity bonds of the silicon nitride layer 103(n2) that is under formation by the low frequency, thus breaking the bonds. This forms the silicon nitride layer 103(n2) having compressive stress.

Furthermore, the process gas turns into a high density plasma state by the high frequency and the nitrogen ions are irradiated to the wafer 100 by the low frequency. Thus, it is possible to increase a deposition rate, compared with only the high frequency as in step S202. It is therefore possible to form the silicon nitride layer 103(n2) at an early stage.

In some embodiments, in the process of the process chamber 201b in step S204, an assist gas for assisting breaking the bonds of an impurity such as argon (Ar) or the like may be included in the process gas. Since a molecular size of Ar is greater than that of nitrogen, it is possible to promote breaking of a bonding portion of the impurity bonds generated when the silicon nitride layer 103(n2) is formed. At this time, in order to adjust the stress, a supply amount of Ar may be adjusted. The MFC 343 or the valve 344 is controlled to adjust the supply amount of Ar. For example, it is adjusted such that the supply amount of Ar is increased to lower the stress and decreased to elevate the stress.

In this manner, the tensile stress, which is the film stress of the silicon nitride layer 103(n2), can be reduced by breaking the bond to the impurity.

However, in this step, not only the bond to the impurity but also the Si—N bond may be broken. For example, when broken, it is considered that the film quality, including decreased film density or increased etching rate, may deteriorate. However, as illustrated in FIG. 7, since the sacrificial film 104 is removed in a subsequent sacrificial film removing step S114, even if the film quality deteriorates, there is no problem.

In some embodiments, the low frequency may be supplied in the form of a pulse. This is because, since ions or electrons having high energy such as nitrogen or the like constantly collide with the wafer 100 to react with each other as the low frequency is continuously applied, the temperature of the silicon nitride layer 103(n2) may be rapidly increased to affect another film. Such a constant reaction can be prevented by supplying the low frequency in the form of a pulse. It is therefore possible to suppress the temperature increase of the silicon nitride layer 103(n2).

### (S205)

Here, step S205 of moving the first wafer 100 and the second wafer 100 and loading the third wafer 100 will be described. If the silicon nitride layer 103(n2) is formed on the first wafer 100 and the silicon nitride layer 103(n1) is formed on the second wafer 100 after the lapse of a predetermined time, the supply of the process gas is stopped. Thereafter, the rotary tray 224 is elevated to separate the substrate from the substrate mounting surface 211a and the substrate mounting surface 211b. Thus, the first wafer 100 is mounted on the substrate mounting surface 211c and the second wafer 100 is mounted on the substrate mounting surface 211b by the same method as that of step S203. Furthermore, the third wafer 100 is carried into and mounted on the hold portion 224. Similar to other wafers 100, the third wafer 100 is mounted on the substrate mounting surface 211a.

### (S206)

Here, step S206 of processing the substrate in the process chamber 201a, the process chamber 201b and the process chamber 201c in which the wafers 100 are located will be described.

### (Process in Process Chamber 201a)

The same process as that of step S202 is performed in the process chamber 201a to form a silicon nitride layer 103(n1) on the insulating film 102 of the third wafer 100.

### (Process in Process Chamber 201b)

The same process as that of step S204 is performed in the process chamber 201b to form a silicon nitride layer 103(n2) on the silicon nitride layer 103(n1) of the second wafer 100.

### (Process in Process Chamber 201c)

The same process as that of step S204 in the process chamber 201b is performed in the process chamber 201c to form a silicon nitride layer 103(n3) on the silicon nitride layer 103(n2) of the first wafer 100. Here, both the high frequency and the low frequency are supplied at a level similar to that of the process chamber 201b to form a film having low film stress in the same manner as the silicon nitride layer 103(n2).

### (S207)

Here, step S207 of moving the first wafer 100, the second wafer 100, and the third wafer 100 and loading the fourth wafer 100 will be described.

If the silicon nitride layer 103(n3) is formed on the first wafer 100, the silicon nitride layer 103(n2) is formed on the second wafer 100, and the silicon-containing layer n1 is formed on the third wafer 100, and after the lapse of a predetermined time, the supply of the process gas is stopped. Thereafter, the rotary tray 224 is elevated to separate the substrate from the substrate mounting surface 211a, the substrate mounting surface 211b, and the substrate mounting surface 211c. Thus, the first wafer 100 is mounted on the substrate mounting surface 211d, the second wafer 100 is mounted on the substrate mounting surface 211c, and the third wafer 100 is mounted on the substrate mounting surface 211b by the same method as that of steps S203 and S205. Furthermore, the fourth wafer 100 is carried into and mounted on the hole portion 224b. Similar to other wafers 100, the third wafer 100 is mounted on the substrate mounting surface 211a.

### (S208)

Here, step S208 of processing the substrate in the process chamber 201a, the process chamber 201b, the process chamber 201c, and the process chamber 201d in which the wafers 100 are located will be described.

### (Process in Process Chamber 201a)

The same process as that of step S202 is performed in the process chamber 201a to form a silicon nitride layer 103(n1) on the insulating film 102 of the fourth wafer 100.

### (Process in Process Chamber 201b)

The same process as that of step S204 is performed in the process chamber 201b to form a silicon nitride layer 103(n2) on the silicon nitride layer 103(n1) of the third wafer 100.

### (Process in Process Chamber 201c)

The same process as that of step S206 is performed in the process chamber 201c to form a silicon nitride layer 103(n3) on the silicon nitride layer 103(n2) of the second wafer 100.

### (Process in Process Chamber 201d)

The same process as that in the process chamber 201a is performed in the process chamber 201d to form a silicon nitride layer 103(n4) on the silicon nitride layer 103(n3) of the first wafer 100.

### (S209)

Here, step S209 of moving the first wafer 100, the second wafer 100, the third wafer 100, and the fourth wafer 100 and replacing the first wafer 100 by a wafer 100 to be newly processed will be described.

When the film formation is completed, the rotary tray 222 is relatively elevated to separate each wafer 100 from the substrate mounting part 211 and rotate each wafer 100 by 90 degrees. When the wafer 100 is moved onto the substrate mounting surface 100a, the gate valve 208 is opened and the first wafer 100 is substituted by a new wafer 100. Thereafter, the processes of steps S202 to S209 may be repeated until the process of a predetermined number of substrates is completed.

As described above, by forming the sacrificial film 104 in which the compressive stress of the silicon nitride layer 103(n2) and the silicon nitride layer 103(n3) is reduced, it is possible to limit the breakdown or the yield reduction of the semiconductor device, which is caused by a stress difference or the like even if the insulating film 102 and the sacrificial film 104 are alternately laminated as in FIGS. 4 to 6.

However, the insulating films 102 are formed above and below the sacrificial film 104 that include the silicon nitride layer 103(n1), the silicon nitride layer 103(n2), the silicon nitride layer 103(n3), and the silicon nitride layer 103(n4), as illustrated in FIG. 4.

The insulating film 102 has an oxygen component mixed therein. Thus, consideration should be given to the case when the wafer 100 is heated, the oxygen component migrates to the sacrificial film 104. In particular, in the case of a film in which a bond is broken like the silicon nitride layers 103(n2) and 103(n3), it is likely that the migrated oxygen component will penetrate the sacrificial film 104.

Thus, in the present embodiment, the silicon nitride layer 103(n1), which is a dense nitride layer, is formed between the lower insulating film 102 and the silicon nitride layer 103(n2). The dense nitride layer refers to a nitride layer with a high bonding degree. The high bonding degree refers to a state in which bonds of Si and N as main ingredients, or impurity bonds are large. That is to say, it refers to a state in which the dense nitride layer has a bonding degree higher than that of the silicon nitride layer 103(n2). In this case, since the silicon nitride layer 103(n1) serves as a wall, it is possible to prevent the oxygen component of the insulating film 102 formed below the silicon nitride layer 103(n1) from migrating to the silicon nitride layer n2.

Furthermore, in the present embodiment, the silicon nitride layer 103(n4), which is a dense nitride layer, is formed between the upper insulating film 102 and the silicon nitride layer 103(n3). Since the silicon nitride layer 103(n4) serves as a wall, it is possible to prevent the oxygen component of the insulating film 102 formed above the silicon nitride layer 103(n4) from migrating to the silicon nitride layer 103(n3).

The silicon nitride layer 103(n2) and the silicon nitride layer 103(n3) serving to reduce the stress of the entire laminated film in this manner have low film density and are likely to oxidize. As such, it is desirable to form the dense silicon nitride layer 103(n1) or the silicon nitride layer 103(n4) between the insulating film 102 and the silicon nitride layer 103(n2).

For example, unlike the present embodiment, a case where the silicon nitride layer 103(n1) or the silicon nitride layer 103(n4) is not formed is considered. In this case, the oxygen component of the insulating film 102 may penetrate the sacrificial film 104 to oxidize the sacrificial film 104. Since this oxidation is not intended, consideration should be given to the oxygen component being unevenly oxidized.

However, as generally known, if the silicon nitride layer is oxidized, an etching rate may be lowered. When a device is manufactured in such a state, for example, the following problems occur. Although it is attempted to etch the sacrificial film 104 in the sacrificial film removing step S114, a portion of the oxidized sacrificial film 104 cannot be etched. This may cause a variation in the amount being etched.

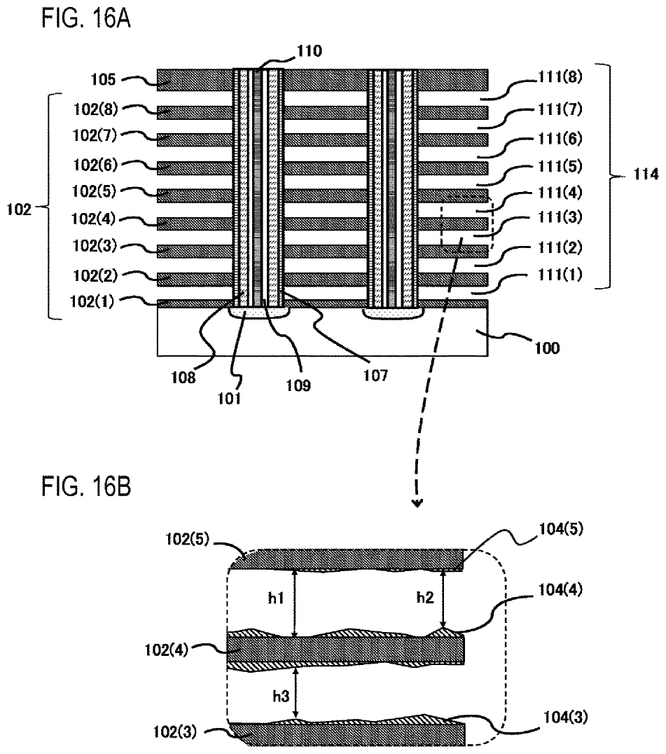

This will be described with reference to FIGS. 16A and 16B which are Comparative examples. FIG. 16A is a view illustrating a state after the oxidized sacrificial film 104 is etched. FIG. 16B is an enlarged view of a portion of FIG. 16A, illustrating a variation in an etching amount mentioned above. When the etching amount varies in this way, an oxidized portion of the sacrificial film 104 may remain above and below the insulating film 102 as illustrated in FIG. 16B.

The variation in the oxidized portion of the sacrificial film 104 refers to a variation in height in a horizontal direction. For example, it refers to a variation in distances h1 and h2 between the insulating film 102(4) (or the remaining sacrificial film 104(4)) and the insulating film 102(5) (or the remaining sacrificial film 104(5)). Or, it refers to a variation in a vertical direction. For example, it refers to a variation in the distance h1 between the insulating film 102(4) (or the remaining sacrificial film 104(4) and the insulating film 102(5) (or the remaining sacrificial film 104(5)) and a distance h3 between the insulating film 102(3) (or the remaining sacrificial film 104(3)) and the insulating film 102(4) (or the remaining sacrificial film 104(4)). When a device is manufactured in such a state, a variation in property such as electrical capacity, a resistance value or the like occurs between the conductive films 112.

On the other hand, by forming the dense silicon nitride layer 103(n1) on the insulating film 102 as in the present embodiment, it is possible to suppress the oxidation of the silicon nitride layer 103(n2).

Furthermore, while in the present embodiment, the sacrificial film 104 has been described to be formed in four divided layers, the present disclosure is not limited thereto. As an example, the sacrificial film 104 may be divided into three layers or five or more layers as long as a silicon nitride layer with low density can be inserted between the dense silicon nitride layers. In this case, the number of process chambers or the number of rotations may be adjusted depending on the number of layers to be formed.

### Second Embodiment

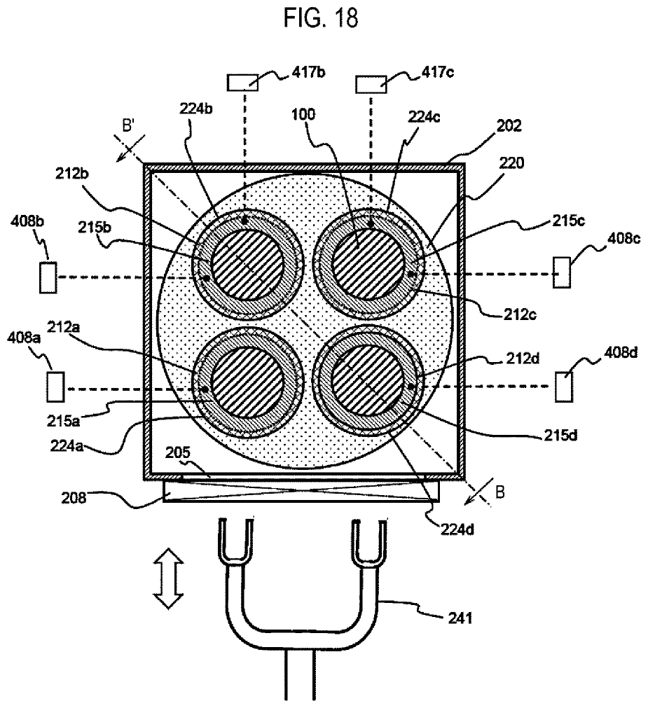

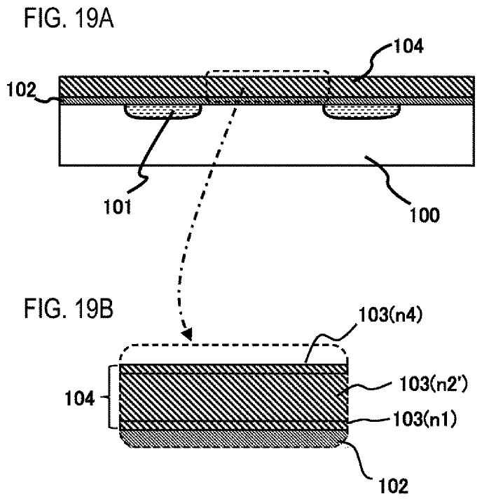

Next, a second embodiment will be described with reference to FIGS. 18, 19A and 19B.

FIG. 18 illustrates a structure equivalent to that of FIG. 10. The difference from FIG. 10 is that the size of the substrate loading/unloading port 205 is different. Specifically, in the structure illustrated in FIG. 18, the substrate loading/unloading port 205 is wider in a horizontal direction than that of the structure of FIG. 10, and has a structure which allows the arm 241 configured to simultaneously transfer two wafers 100 to pass therethrough. In this connection, other components are similar to those of FIG. 10 except that the size of the gate valve 208 or the structure of the arm 241 is different from those of FIG. 10.

Subsequently, a substrate processing method according to the second embodiment will be described.

### (S301)

Here, step S301 of loading two wafers 100 (the first wafer 100 and the second wafer 100) mounted on the arm 241 will be described. Furthermore, a state before the loading of the wafers 100 is a state in which the hole portion 224a and the hole portion 224d are adjacent to the substrate loading/unloading port 205. Thus, the hole portion 224a is arranged on the substrate mounting surface 211a, and the hole portion 224d is arranged on the substrate mounting surface 211d.

The arm 241 enters the process chamber 201 from the substrate loading/unloading port 205 and mounts the first wafer 100 and the second wafer 100 on each of which the insulating film 102 is formed on the hole portion 224a and the hole portion 224d, respectively. Thereafter, the first wafer 100 is mounted on the substrate mounting surface 211a and the second wafer 100 is mounted on the substrate mounting surface 211d, according to the same process as that of step S201 described above.

### (S302)

Here, step S302 of forming a silicon nitride layer 103(n1) on the surface of the insulating film 102 will be described. Similar to the process of step S202, if the wafer 100 is maintained at a predetermined temperature, an HCDS gas is supplied from the first gas supply system 310 to the process chamber 201a and an NH₃ gas is also supplied from the second gas supply system 320 to the process chamber 201a. Furthermore, similarly, an HCDS gas is supplied from the first gas supply system 310 to the process chamber 201b and an NH₃ gas is also supplied from the second gas supply system 320 to the process chamber 201b.

Subsequently, if the interior of the process chamber 201 reaches a predetermined pressure, the plasma generation part 400 starts to supply a high frequency into the process chamber 201 to generate plasma in the process chamber 201a and the process chamber 201d. The HCDS gas and the NH₃ gas in a plasma state react with each other in the process chamber 201a and are supplied onto the insulating film 102, thus forming a dense silicon nitride layer 103(n1) on each of the first wafer 100 and the second wafer 100.

The thickness of the silicon nitride layer 103(n1) is set such that it does not have an affect on the stress of the sacrificial film and is thinner than at least a silicon nitride layer 103(n2) to be formed later.

### (S303)

Here, step S303 of moving the first wafer 100 and the second wafer 100 and loading the third wafer 100 and the fourth wafer 100 will be described.

If the silicon nitride layer 103(n1) is formed on each of the first wafer 100 and the second wafer 100, the supply of the process gas is stopped. Thereafter, the wafer 100 is separated by the same method as that of step S202. After the separation, the rotary tray 224 is rotated by 180 degrees in a clockwise direction such that the hole portion 224a is above the substrate mounting surface 211c and the hole portion 224d is above the substrate mounting surface 211b. When the rotation is completed, the gate valve 208 is opened and the third wafer 100 is mounted on the hole portion 224c and the fourth wafer 100 is mounted on the hole portion 244b. After each wafer 100 is mounted on the respective hole portion 224, each substrate mounting surface 211 is relatively elevated to mount the first wafer 100 positioned in the hole portion 224a on the substrate mounting surface 211c, the second wafer 100 positioned in the hole portion 224d on the substrate mounting surface 211b, the third wafer 100 positioned in the hole portion 224c on the substrate mounting surface 211a, and the fourth wafer 100 positioned in the hole portion 224b on the substrate mounting surface 211d.

### (S304)

Here, step S304 of processing the substrate in the process chamber 201a, the process chamber 201b, the process chamber 201c, and the process chamber 201d will be described.

### (Process in Process Chamber 201a and Process Chamber 201d)

The same process as that of step S202 is performed in the process chamber 201a to form a silicon nitride layer 103(n1) on the insulating film 102 of each of the third wafer 100 and the fourth wafer 100.

### (Process in Process Chamber 201b and Process Chamber 201c)

In the process chamber 201b and the process chamber 201c, a silicon nitride layer 103(n2′) as illustrated in FIG. 19B is formed on the silicon nitride layer 103(n1) of the first wafer 100 by supplying a high frequency and a low frequency using the same method as that of step S206. Similarly, even in the process chamber 201b, a silicon nitride layer 103(n2′) as illustrated in FIG. 19B is similarly formed on the silicon nitride layer 103(n1) of the second wafer 100 by supplying a high frequency and a low frequency. An ion component such as nitrogen or the like is supplied to the impurity bond of the silicon nitride layer 103(n2) during the forming process by the low frequency, so that the bond is broken. Thus, a silicon nitride layer 103 (n2′) having compressive stress is formed.

### (S305)

Here, step S305 of moving the first wafer 100, the second wafer 100, the third wafer 100 and the fourth wafer 100 will be described.

If the desired silicon nitride layers 103(n1) and 103(n2′) are formed in each process chamber, the supply of the process gas is stopped. Thereafter, the wafer 100 is separated by the same method as that of step S302. After the separation, the rotary tray 224 is rotated by 180 degrees in a clockwise direction such that the hole portion 224a is above the substrate mounting surface 211a and the hole portion 224d is above the substrate mounting surface 211d. At this time, the hole portion 224b is arranged above the substrate mounting surface 211b and the hole portion 224c is arranged above the substrate mounting surface 211c.

### (S306)

Here, step S306 of processing the substrate in the process chamber 201a, the process chamber 201b, the process chamber 201c, and the process chamber 201d will be described.

Upon completion of the movement, the same process as that of step S305 is performed to form a silicon nitride layer 103(n4) on each of the first wafer 100 and the second wafer 100. Furthermore, a silicon nitride layer 103(n2′) is formed on each of the third wafer 100 and the fourth wafer 100.

### (S307)

Here, step S307 of unloading the first wafer 100 and the second wafer 100 will be described.

Upon completion of the process of step S306, the gate valve 208 is opened and the first wafer 100 and the second wafer 100 are unloaded. At this time, when there are wafers 100 to be subsequently processed, those wafers 100 are mounted on the hole portions 224a and 224d. Thereafter, the process of steps S302 to S307 may be repeated until the process of a predetermined number of substrates is completed.

As described above, by forming the sacrificial film 104 in which the compressive stress of the silicon nitride layer 103(n2) is reduced, it is possible to limit the breakdown or the yield reduction of the semiconductor device, which is caused by a stress difference or the like, even if the insulating film 102 and the sacrificial film 104 are alternately laminated as illustrated in FIGS. 4 to 6.

Furthermore, in the aforementioned embodiment, it is desirable that a high-frequency power supplied from the high-frequency power sources 402 (402b and 402c) in the two-frequency process chamber is set to be greater than that of the single frequency process chamber. The decomposition can be promoted by increasing the electric power. Thus, it is possible to further enhance a deposition rate. Therefore, even when the process is performed for the same period of time as that of the single frequency process chamber, it is possible to form a silicon nitride layer that is thicker than the silicon nitride layer formed in the single frequency process chamber.

In addition, when forming each silicon nitride layer 103, the supply amount of a silicon-containing gas to each process chamber may be adjusted. For example, the supply amount may be adjusted by setting the supply time of a silicon-containing gas to the single frequency process chamber to be shorter than the supply time of a silicon-containing gas to the two-frequency process chamber by controlling each valve 302 and each MFC 303. In this manner, it is possible to more accurately control the thickness of each silicon nitride layer.

Moreover, in some embodiments, in the process in the two-frequency process chamber, an assist gas for assisting breaking bonding of an impurity such as Ar or the like may be included in the process gas. Since Ar has a molecular size larger than that of nitrogen, it is possible to promote breaking of a bonding portion of the impurity bond generated when the silicon nitride layer 103(n2) or the silicon nitride layer 103(n3) is formed. At this time, in order to adjust the stress, the supply amount of Ar may be adjusted. When adjusting the supply amount of Ar, the MFC 343 or the valve 344 may be adjusted. For example, in order to reduce the stress, the MFC 343 or the valve 344 may be adjusted to increase the supply amount of Ar, and in order to increase the stress, the MFC 343 or the valve 344 may be adjusted to decrease the supply amount of Ar.

In this manner, it is possible to reduce the tensile stress, which is the film stress of the silicon nitride layer 103(n2), the silicon nitride layer 103(n3), or the silicon nitride layer 103(n2′), by breaking the bond to the impurity.

In some embodiments, the low frequency may be supplied in the form of a pulse. This is because, since the ions or electrons having high energy, such as nitrogen or the like, constantly collide with the wafer 100 to react with each other as the low frequency is continuously applied, the temperature of the silicon nitride layer 103(n2) or the silicon nitride layer 103(n3) may be rapidly increased to affect another film. Since the constant reaction can be prevented by supplying the low frequency in the form of a pulse, it is possible to limit the increase in the temperature of the silicon nitride layer 103(n2) or the silicon nitride layer 103(n3).

Furthermore, in the aforementioned embodiment, there has been described an example in which the breakdown of the semiconductor device occurs due to a difference in thermal expansion coefficient between the insulating film and the sacrificial film, but the present disclosure is not limited thereto. For example, when the holes 106 illustrated in FIGS. 5A and 5B are formed, there is a possibility that the breakdown of the semiconductor device occurs due to a problem of film stress of the insulating film or the sacrificial film. However, by reducing the film stress of the insulating film or reducing the film stress of the sacrificial film as in the aforementioned embodiment, it is possible to prevent the breakdown of the semiconductor device when forming the hole 106.

Moreover, in the aforementioned embodiment, there has been described a structure in which the gas introduction hole 233 is formed in the shower head 230, but the present disclosure is not limited thereto. In some embodiments, any structure may be used as long as it can supply an assist gas to the two-frequency process chamber. For example, it may be configured such that the downstream side of the valve 344b communicates with the downstream side of valve 302b, and the downstream side of the valve 344c communicates with the downstream side of the valve 302c.

In addition, while the sacrificial film has been described to be formed by simultaneously supplying two gases to the process chamber, the present disclosure is not limited thereto. For example, the sacrificial film may be formed on the insulating film 102 by performing an alternate supply process of alternately supplying the gases. Specifically, a layer mainly formed of silicon may be formed by supplying an HCDS gas onto the insulating film 102, and subsequently, ammonia may be supplied and decomposed to react with the layer mainly formed of silicon to form a SiN layer. Alternatively, the alternate supply process may be performed in step S201 in which a dense film is required, and the film may be formed by simultaneously supplying the gases to the process chamber as in the aforementioned embodiment in step S202 in which a high deposition rate is required. In this case, the reaction may be promoted by activating any one of the HCDS gas and the NH₃ gas or the both.

Furthermore, in the present embodiment, the low-frequency power source has been described to be used as one component of the ion control part 410, but the present disclosure is not limited thereto. For example, a high-frequency power source may be used as long as it can attract an ion component. However, it is possible that the low-frequency power source is used to control migration of ions more greatly, compared with the high-frequency power source, in terms of the characteristics of each power source. Thus, it is desirable to use the low frequency.

In addition, while in FIG. 4 or the like, the insulating film 102 and the sacrificial film 104 has been described to be alternately formed as eight layers, the present disclosure is not limited thereto. For example, the insulating film 102 and the sacrificial film 104 may be formed in more than eight layers. As the number of layers increases, it may be easily affected by the stress. Thus, the technique described in the present embodiment is more effective.

According to the present disclosure in some embodiments, it is possible to provide a technique capable of forming a semiconductor device with good characteristics even in a flash memory having a three-dimensional structure.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of manufacturing a semiconductor device, comprising:
transferring a substrate on which an insulating film is formed to a single frequency process chamber installed inside a process module;
forming a first silicon nitride layer on the insulating film by supplying a silicon-containing gas containing at least silicon and an impurity into the single frequency process chamber and supplying, by a plasma generation part, a high frequency into the single frequency process chamber;
transferring the substrate to a two-frequency process chamber installed adjacent to the single frequency process chamber inside the process module by a substrate transfer part installed inside the process module and configured to transfer the substrate between the single frequency process chamber and the two-frequency process chamber; and
forming a second silicon nitride layer, which has a stress that is lower than a stress of the first silicon nitride layer, on the first silicon nitride layer by supplying the silicon-containing gas into the two-frequency process chamber, supplying, by the plasma generation part, a high frequency into the two-frequency process chamber, and supplying, by an ion controller, a low frequency into the two-frequency process chamber.

2. The method of claim 1, wherein the single frequency process chamber is installed in a plural number,
a first single frequency process chamber of the plural number of single frequency process chambers is installed at an upstream side in a movement direction of the substrate when viewed from the two-frequency process chamber, and
a second single frequency process chamber of the plural number of single frequency process chambers is installed at a downstream side in the movement direction of the substrate when viewed from the two-frequency process chamber.

3. The method of claim 2, wherein the substrate transfer part includes a rotary shaft, and a rotary tray on which a plurality of substrates are mounted in a circumferential shape.

4. The method of claim 3, wherein the ion controller includes a low-frequency power source, and
wherein the low-frequency power source supplies a low frequency in the form of a pulse into the two-frequency process chamber in the act of forming the second silicon nitride layer.

5. The method of claim 4, wherein an assist gas supply part configured to supply argon is connected to the two-frequency process chamber, and
wherein the act of forming the second silicon nitride layer includes supplying argon from the assist gas supply part into the two-frequency process chamber.

6. The method of claim 3, wherein an assist gas supply part configured to supply argon is connected to the two-frequency process chamber, and
wherein the act of forming the second silicon nitride layer includes supplying argon from the assist gas supply part into the two-frequency process chamber.

7. The method of claim 2, wherein the ion controller includes a low-frequency power source, and
wherein the low-frequency power source supplies a low frequency in the form of a pulse into the two-frequency process chamber in the act of forming the second silicon nitride layer.

8. The method of claim 7, wherein an assist gas supply part configured to supply argon is connected to the two-frequency process chamber, and
wherein the act of forming the second silicon nitride layer includes supplying argon from the assist gas supply part into the two-frequency process chamber.

9. The method of claim 2, wherein an assist gas supply part configured to supply argon is connected to the two-frequency process chamber, and
wherein the act of forming the second silicon nitride layer includes supplying argon from the assist gas supply part into the two-frequency process chamber.

10. The method of claim 1, wherein the substrate transfer part includes a rotary shaft, and a rotary tray on which a plurality of substrates are mounted in a circumferential shape.

11. The method of claim 10, wherein the ion controller includes a low-frequency power source, and
wherein the low-frequency power source supplies a low frequency in the form of a pulse into the two-frequency process chamber in the act of forming the second silicon nitride layer.

12. The method of claim 11, wherein an assist gas supply part configured to supply argon is connected to the two-frequency process chamber, and
wherein the act of forming the second silicon nitride layer includes supplying argon from the assist gas supply part into the two-frequency process chamber.

13. The method of claim 10, wherein an assist gas supply part configured to supply argon is connected to the two-frequency process chamber, and
wherein the act of forming the second silicon nitride layer includes supplying argon from the assist gas supply part into the two-frequency process chamber.

14. The method of claim 1, wherein the ion controller includes a low-frequency power source, and
wherein the low-frequency power source supplies a low frequency in the form of a pulse to the two-frequency process chamber in the act of forming the second silicon nitride layer.

15. The method of claim 14, wherein an assist gas supply part configured to supply argon is connected to the two-frequency process chamber, and
wherein the act of forming the second silicon nitride layer includes supplying argon from the assist supply part into the two-frequency process chamber.

16. The method of claim 1, wherein an assist gas supply part configured to supply argon is connected to the two-frequency process chamber, and
wherein the act of forming the second silicon nitride layer includes supplying argon from the assist supply part into the two-frequency process chamber.
